(19) United States
(12) Patent Application Publication
(10) Pub. No.: US 2026/0186893 A1
(43) Pub. Date: Jul. 2, 2026

(54) Latch-Based Low-Density Parity Check (LDPC) Implementations

(71) Applicant: SK Hynix NAND Product Solutions Corp. (dba Solidigm), Rancho Cordova, CA (US)

(72) Inventor: Zion KWOK, Burnaby (CA)

(21) Appl. No.: 19/002,482

(22) Filed: Dec. 26, 2024

(51) Int. Cl. G06F 11/10; H03K 19/017

(52) U.S. Cl. CPC G06F 11/1004; G06F 11/1048; H03K 19/01728

(57) ABSTRACT

This application is directed to data validation and correction in an electronic device that includes an input data interface, a plurality of input latch units, a logic, and an output unit. The input data interface is configured to receive a plurality of check node data items each including parallel input bits. Each input latch unit corresponds to a respective check node data item and includes a plurality of parallel input latches configured to be controlled by a control signal to hold the parallel input bits of the respective check node data item. The logic configured to process the plurality of check node data items and generate a variable node data item including a plurality of parallel output bits. The output unit is configured to be controlled by the control signal to hold the parallel output bits of the variable node data item.

### TECHNICAL FIELD

This application relates generally to memory management including, but not limited to, methods, systems, devices, circuits, and non-transitory computer-readable media for validating and correcting data stored in a memory device (e.g., solid-state drive).

### BACKGROUND

Memory is applied in a computer system to store instructions and data. The data are processed by one or more processors of the computer system according to the instructions stored in the memory. Multiple memory units are used in different portions of the computer system to serve different functions. Specifically, the computer system includes non-volatile memory that acts as secondary memory to keep data stored thereon if the computer system is decoupled from a power source. Examples of the secondary memory include, but are not limited to, hard disk drives (HDDs) and solid-state drives (SSDs). Min-Sum and Bit-Flipping algorithms are widely used for detecting and correcting bit errors in user data stored in memory, often utilizing integrity data such as low-density parity-check (LDPC) codes. However, implementing these algorithms typically requires significant computational resources.

### SUMMARY

Various embodiments of this application are directed to applying latches in place of flip-flops of a data correction decoder (e.g., a min-sum decoder, a bit flipping decoder) to reduce a gate count of controller circuitry and improve utilization of computational resources of a storage device (e.g., an SSD). In some embodiments, during LDPC decoding, check node data of a plurality of check nodes may be stored in flip-flops (e.g., edge-triggered D flip-flops), and a subset of check node data associated with a subset of check nodes is selected by multiplexers and processed during each clock cycle. In some embodiments, the edge-triggered D flip-flops are replaced with smaller level-triggered gated D latches, and each D latch includes a smaller number of transistors than a D flip-flop, thereby reducing an overall gate count needed to store the check node data. More specifically, an LDPC decoder includes a plurality of input latches, a multiplexing logic, and a plurality of output latches. The input latches include a first number of latches, and the output latches include a second number of latches, where the second number is smaller than the first number. In an example, the gate count of the LDPC decoder is reduced by approximately 1.5 gates per stored data bit of the check node data when D flip-flop are at least partially replaced with D latches. A min-sum decoder having 5120 check nodes and 17 bits in each check node can save approximately 130 K gates, thereby reserving limited computation resources of a memory controller.

In one aspect, an electronic device includes an input data interface, a plurality of input latch units coupled to the input data interface, a logic coupled to the plurality of input latch units, and an output unit coupled to the logic. The input data interface is configured to receive a plurality of check node data items, and each check node data item includes a plurality of parallel input bits. Each input latch unit corresponds to a respective check node data item, and includes a plurality of parallel input latches configured to be controlled by a control signal to hold the plurality of parallel input bits of the respective check node data item. The logic is configured to process the plurality of check node data items and generate a variable node data item including a plurality of parallel output bits. The output unit is configured to be controlled by the control signal to hold the plurality of parallel output bits of the variable node data item.

Some implementations of this application include an electronic device includes an application-specific integrated circuit (ASIC) and memory having instructions stored thereon and executed to configure the ASIC to provide an input data interface, a plurality of input latch units coupled to the input data interface, a logic coupled to the plurality of input latch units, and an output latch unit coupled to the logic.

In another aspect, a method is implemented at an electronic device to validate data for a memory system (e.g., SSDs). The method includes obtaining a plurality of check node data items, and each check node data item includes a plurality of parallel input bits. The method further includes controlling a plurality of input latch units each of which corresponds to a respective check node data item and includes a plurality of parallel input latches with a control signal to hold the plurality of parallel input bits of the respective check node data item. The method further includes processing the plurality of check node data items and generating a variable node data item including a plurality of parallel output bits. The method further includes controlling an output unit with the control signal to hold the plurality of parallel output bits of the variable node data item.

Some implementations of this application include a memory system or device that includes one or more processors and memory having instructions stored thereon, which when executed by the one or more processors cause the one or more processors to perform any of the methods described herein.

Some implementations of this application include a memory system or device that includes one or more processors and memory having instructions stored thereon, which when executed by the one or more processors cause the one or more processors to perform any of the methods described herein.

Some implementations include a non-transitory computer readable storage medium storing one or more programs. The one or more programs include instructions, which when executed by one or more processors cause the processors to implement any of the methods on a memory system or device (e.g., SSDs).

In some embodiments, the above methods, electronic devices, memory systems or devices, or non-transitory computer readable storage medium for processing LDPC-based check node data are also used in communication (e.g., wireless communication using 5G or Wi-Fi technology, satellite communications, Ethernet communication, and communication via fiber Optic networks).

These illustrative embodiments and implementations are mentioned not to limit or define the disclosure, but to provide examples to aid understanding thereof. Additional embodiments are discussed in the Detailed Description, and further description is provided there.

### BRIEF DESCRIPTION OF THE DRAWINGS

For a better understanding of the various described implementations, reference should be made to the Detailed Description below, in conjunction with the following drawings in which like reference numerals refer to corresponding parts throughout the figures.

FIG. 1 is a block diagram of an example system module in a typical electronic device, in accordance with some embodiments.

FIG. 2 is a block diagram of a memory system of an example electronic device having one or more memory access queues, in accordance with some embodiments.

FIG. 3 is a block diagram of an example integrity check system of a memory system for processing a codeword, in accordance with some embodiments.

FIG. 4A is a Tanner graph applied to implement LDPC coding using check nodes and variable nodes, in accordance with some embodiments.

FIG. 4B is a simplified Tanner graph having a single check node coupled to a set of variable nodes, in accordance with some embodiments.

FIG. 4C is another simplified Tanner graph having a single variable node coupled to a set of check nodes, in accordance with some embodiments.

FIG. 5A is a schematic diagram of a sequence of check node operations implemented to determine check node data of a check node during LDPC decoding, in accordance with some embodiments.

FIG. 5B is a schematic diagram of a sequence of variable node operations implemented to determine variable node data of a variable node during LDPC decoding, in accordance with some embodiments.

FIG. 6 is a schematic diagram of an example circuit for updating variable node data based on check node data, in accordance with some embodiments.

FIG. 7A illustrates a schematic diagram and an associated truth table of an example latch circuit, in accordance with some embodiments.

FIG. 7B is a schematic diagram of an example flip flop circuit, in accordance with some embodiments.

FIGS. 8A, 8B, and 8C are schematic diagrams of three example latch-based circuits for processing check node data of a plurality of check nodes, in accordance with some embodiments, respectively.

FIG. 9 is a flow diagram of an example process for processing check node data, in accordance with some embodiments.

Like reference numerals refer to corresponding parts throughout the several views of the drawings.

### DETAILED DESCRIPTION

Reference will now be made in detail to specific embodiments, examples of which are illustrated in the accompanying drawings. In the following detailed description, numerous non-limiting specific details are set forth in order to assist in understanding the subject matter presented herein. But it will be apparent to one of ordinary skill in the art that various alternatives may be used without departing from the scope of claims and the subject matter may be practiced without these specific details. For example, it will be apparent to one of ordinary skill in the art that the subject matter presented herein can be implemented on many types of electronic devices with digital video capabilities.

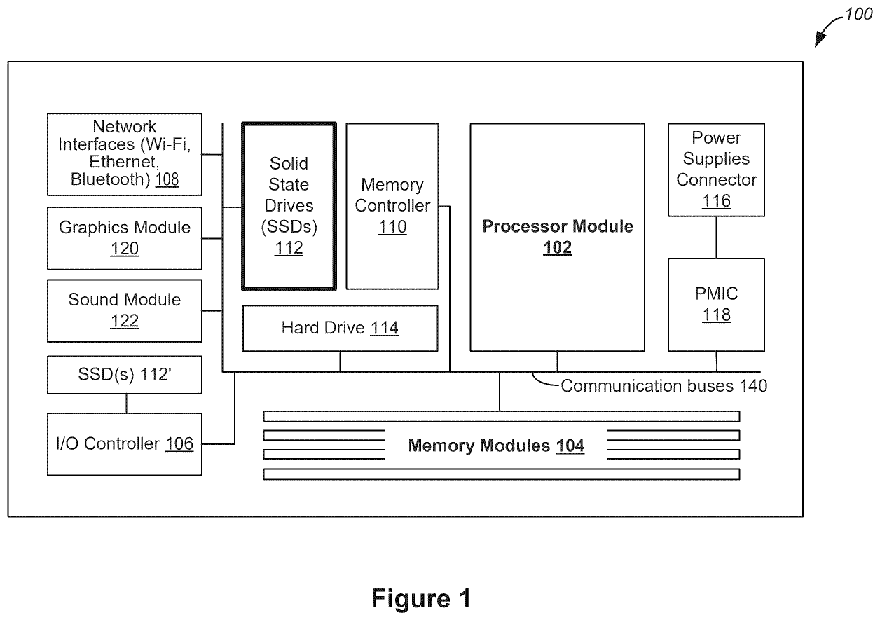

FIG. 1 is a block diagram of an example system module 100 in a typical electronic system in accordance with some embodiments. The system module 100 in this electronic system includes at least a processor module 102, memory modules 104 for storing programs, instructions and data, an input/output (I/O) controller 106, one or more communication interfaces such as network interfaces 108, and one or more communication buses 140 for interconnecting these components. In some embodiments, the I/O controller 106 allows the processor module 102 to communicate with an I/O device (e.g., a keyboard, a mouse or a trackpad) via a universal serial bus interface. In some embodiments, the network interfaces 108 includes one or more interfaces for Wi-Fi, Ethernet and Bluetooth networks, each allowing the electronic system to exchange data with an external source, e.g., a server or another electronic system. In some embodiments, the communication buses 140 include circuitry (sometimes called a chipset) that interconnects and controls communications among various system components included in system module 100.

In some embodiments, the memory modules 104 include high-speed random-access memory, such as static random-access memory (SRAM), double data rate (DDR) dynamic random-access memory (DRAM), or other random-access solid state memory devices. In some embodiments, the memory modules 104 include non-volatile memory, such as one or more magnetic disk storage devices, optical disk storage devices, flash memory devices, or other non-volatile solid state storage devices. In some embodiments, the memory modules 104, or alternatively the non-volatile memory device(s) within the memory modules 104, include a non-transitory computer readable storage medium. In some embodiments, memory slots are reserved on the system module 100 for receiving the memory modules 104. Once inserted into the memory slots, the memory modules 104 are integrated into the system module 100.

In some embodiments, the system module 100 further includes one or more components selected from a memory controller 110, SSD(s) 112, an HDD 114, power management integrated circuit (PMIC) 118, a graphics module 120, and a sound module 122. The memory controller 110 is configured to control communication between the processor module 102 and memory components, including the memory modules 104, in the electronic system. The SSD(s) 112 are configured to apply integrated circuit assemblies to store data in the electronic system, and in many embodiments, are based on NAND or NOR memory configurations. The HDD 114 is a conventional data storage device used for storing and retrieving digital information based on electromechanical magnetic disks. The power supply connector 116 is electrically coupled to receive an external power supply. The PMIC 118 is configured to modulate the received external power supply to other desired DC voltage levels, e.g., 5V, 3.3V or 1.8V, as required by various components or circuits (e.g., the processor module 102) within the electronic system. The graphics module 120 is configured to generate a feed of output images to one or more display devices according to their desirable image/video formats. The sound module 122 is configured to facilitate the input and output of audio signals to and from the electronic system under control of computer programs.

Alternatively or additionally, in some embodiments, the system module 100 further includes SSD(s) 112′ coupled to the I/O controller 106 directly. Conversely, the SSDs 112 are coupled to the communication buses 140. In an example, the communication buses 140 operates in compliance with Peripheral Component Interconnect Express (PCIe or PCI-E), which is a serial expansion bus standard for interconnecting the processor module 102 to, and controlling, one or more peripheral devices and various system components including components 110-122.

Further, one skilled in the art knows that other non-transitory computer readable storage media can be used, as new data storage technologies are developed for storing information in the non-transitory computer readable storage media in the memory modules 104, SSD(s) 112 or 112′, and HDD 114. These new non-transitory computer readable storage media include, but are not limited to, those manufactured from biological materials, nanowires, carbon nanotubes and individual molecules, even though the respective data storage technologies are currently under development and yet to be commercialized.

Some implementations of this application are directed to an integrity check process implemented by a memory system (e.g., SSD 112, memory module 104, HDD 114, memory controller 110), which stores codeword symbols including integrity data, e.g., LDPC codes. The integrity check process is also called a decoding process and visualized by a Tanner graph with variable nodes and check nodes. The variable nodes correspond to the codeword symbols extracted from the memory system. Each check node corresponds to a distinct set of variable nodes, and has check node data configured to identify or correct bit errors in the codeword symbols corresponding to the distinct set of variable nodes. Specifically, messages are exchanged between the variable and check nodes on the Tanner graph to update the variable node data and check node data, until the bit errors are identified and corrected in the codeword symbols.

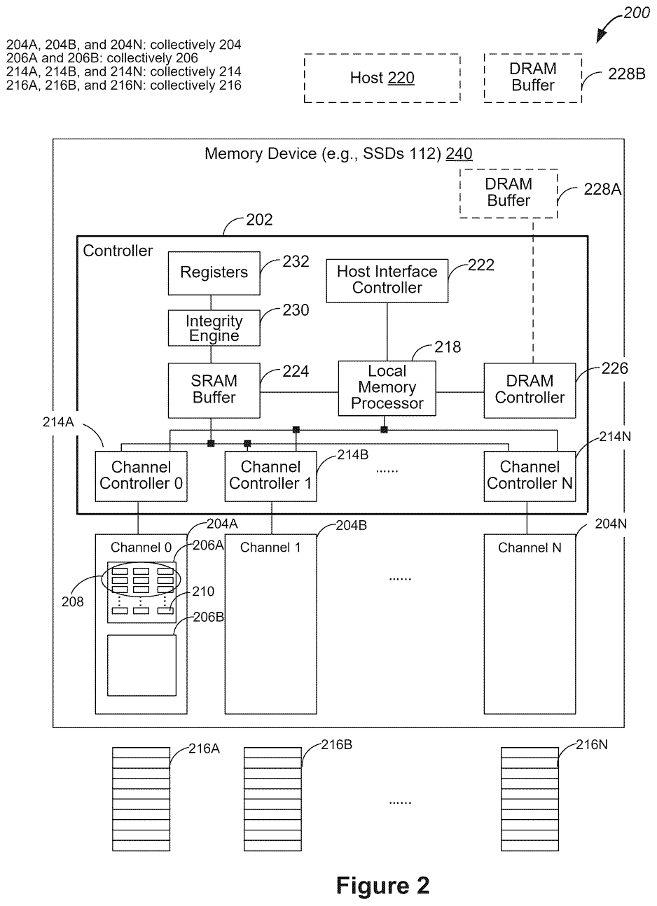

FIG. 2 is a block diagram of a memory system 200 of an example electronic device having one or more memory access queues, in accordance with some embodiments. The memory system 200 is coupled to a host device 220 (e.g., a processor module 102 in FIG. 1) and configured to store instructions and data for an extended time, e.g., when the electronic device sleeps, hibernates, or is shut down. The host device 220 is configured to access the instructions and data stored in the memory system 200 and process the instructions and data to run an operating system and execute user applications. The memory system 200 includes one or more memory devices 240 (e.g., SSD(s)). Each memory device 240 further includes a controller 202 and a plurality of memory channels 204 (e.g., channel 204A, 204B, and 204N). Each memory channel 204 includes a plurality of memory cells. The controller 202 is configured to execute firmware level software to bridge the plurality of memory channels 204 to the host device 220. In some embodiments, each memory device 240 is formed on a printed circuit board (PCB).

Each memory channel 204 includes on one or more memory packages 206 (e.g., two memory dies). In an example, each memory package 206 (e.g., memory package 206A or 206B) corresponds to a memory die. Each memory package 206 includes a plurality of memory planes 208, and each memory plane 208 further includes a plurality of memory pages 210. Each memory page 210 includes an ordered set of memory cells, and each memory cell is identified by a respective physical address. In some embodiments, the memory device 240 includes a plurality of superblocks. Each superblock includes a plurality of memory blocks each of which further includes a plurality of memory pages 210. For each superblock, the plurality of memory blocks are configured to be written into and read from the memory system via a memory input/output (I/O) interface concurrently. Optionally, each superblock groups memory cells that are distributed on a plurality of memory planes 208, a plurality of memory channels 204, and a plurality of memory dies 206. In an example, each superblock includes at least one set of memory pages, where each page is distributed on a distinct one of the plurality of memory dies 206, has the same die, plane, block, and page designations, and is accessed via a distinct channel of the distinct memory die 206. In another example, each superblock includes at least one set of memory blocks, where each memory block is distributed on a distinct one of the plurality of memory dies 206 includes a plurality of pages, has the same die, plane, and block designations, and is accessed via a distinct channel of the distinct memory die 206. The memory device 240 stores information of an ordered list of superblocks in a cache of the memory device 240. In some embodiments, the cache is managed by a host driver of the host device 220, and called a host managed cache (HMC).

In some embodiments, the memory device 240 includes a single-level cell (SLC) NAND flash memory chip, and each memory cell stores a single data bit. In some embodiments, the memory device 240 includes a multi-level cell (MLC) NAND flash memory chip, and each memory cell of the MLC NAND flash memory chip stores 2 data bits. In an example, each memory cell of a triple-level cell (TLC) NAND flash memory chip stores 3 data bits. In another example, each memory cell of a quad-level cell (QLC) NAND flash memory chip stores 4 data bits. In yet another example, each memory cell of a penta-level cell (PLC) NAND flash memory chip stores 5 data bits. In some embodiments, each memory cell can store any suitable number of data bits. Compared with the non-SLC NAND flash memory chips (e.g., MLC SSD, TLC SSD, QLC SSD, PLC SSD), the SSD that has SLC NAND flash memory chips operates with a higher speed, a higher reliability, and a longer lifespan, and however, has a lower device density and a higher price.

Each memory channel 204 is coupled to a respective channel controller 214 (e.g., controller 214A, 214B, or 214N) configured to control internal and external requests to access memory cells in the respective memory channel 204. In some embodiments, each memory package 206 (e.g., each memory die) corresponds to a respective queue 216 (e.g., queue 216A, 216B, or 216N) of memory access requests. In some embodiments, each memory channel 204 corresponds to a respective queue 216 of memory access requests. Further, in some embodiments, each memory channel 204 corresponds to a distinct and different queue 216 of memory access requests. In some embodiments, a subset (less than all) of the plurality of memory channels 204 corresponds to a distinct queue 216 of memory access requests. In some embodiments, all of the plurality of memory channels 204 of the memory device 240 corresponds to a single queue 216 of memory access requests. Each memory access request is optionally received internally from the memory device 240 to manage the respective memory channel 204 or externally from the host device 220 to write or read data stored in the respective channel 204. Specifically, each memory access request includes one of: a system write request that is received from the memory device 240 to write to the respective memory channel 204, a system read request that is received from the memory device 240 to read from the respective memory channel 204, a host write request that originates from the host device 220 to write to the respective memory channel 204, and a host read request that is received from the host device 220 to read from the respective memory channel 204. It is noted that system read requests (also called background read requests or non-host read requests) and system write requests are dispatched by a memory controller to implement internal memory management functions including, but are not limited to, garbage collection, wear levelling, read disturb mitigation, memory snapshot capturing, memory mirroring, caching, and memory sparing.

In some embodiments, in addition to the channel controllers 214, the controller 202 further includes a local memory processor 218, a host interface controller 222, an SRAM buffer 224, and a DRAM controller 226. The local memory processor 218 accesses the plurality of memory channels 204 based on the one or more queues 216 of memory access requests. In some embodiments, the local memory processor 218 writes into and read from the plurality of memory channels 204 on a memory block basis. Data of one or more memory blocks are written into, or read from, the plurality of channels jointly. No data in the same memory block is written concurrently via more than one operation. Each memory block optionally corresponds to one or more memory pages. In an example, each memory block to be written or read jointly in the plurality of memory channels 204 has a size of 16 KB (e.g., one memory page). In another example, each memory block to be written or read jointly in the plurality of memory channels 204 has a size of 64 KB (e.g., four memory pages). In some embodiments, each page has 16 KB user data and 2 KB metadata. Additionally, a number of memory blocks to be accessed jointly and a size of each memory block are configurable for each of the system read, host read, system write, and host write operations.

In some embodiments, the local memory processor 218 stores data to be written into, or read from, each memory block in the plurality of memory channels 204 in an SRAM buffer 224 of the controller 202. Alternatively, in some embodiments, the local memory processor 218 stores data to be written into, or read from, each memory block in the plurality of memory channels 204 in a DRAM buffer 228A that is included in memory device 240, e.g., by way of the DRAM controller 226. Alternatively, in some embodiments, the local memory processor 218 stores data to be written into, or read from, each memory block in the plurality of memory channels 204 in a DRAM buffer 228B that is main memory used by the processor module 102 (FIG. 1). The local memory processor 218 of the controller 202 accesses the DRAM buffer 228B via the host interface controller 222.

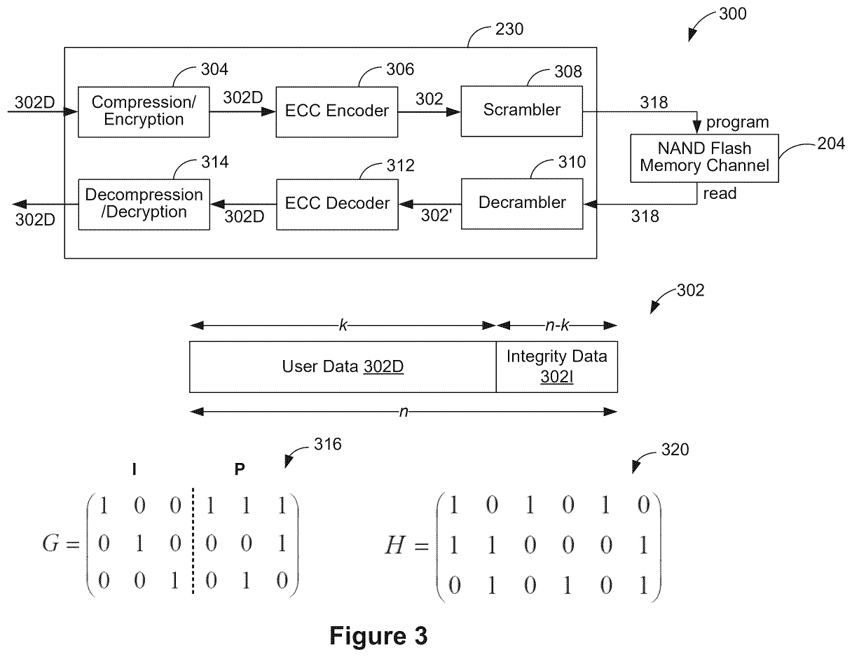

In some embodiments, data in the plurality of memory channels 204 is grouped into coding blocks, and each coding block is called a codeword (FIG. 3, 302). For example, each codeword includes n bits among which k bits correspond to user data and (n−k) corresponds to integrity data of the user data, where k and n are positive integers. In some embodiments, the memory system 200 includes an integrity engine 230 (e.g., an LDPC engine) and a registers 232 including a plurality of registers or SRAM cells or flip-flops and coupled to the integrity engine 230. The integrity engine 230 is coupled to the memory channels 204 via the channel controllers 214 and SRAM buffer 224. Specifically, in some embodiments, the integrity engine 230 has data path connections to the SRAM buffer 224, which is further connected to the channel controllers 214 via data paths that are controlled by the local memory processor 218. The integrity engine 230 is configured to verify data integrity for each coding block of the memory channels 204 using variable nodes and check nodes, and messages are exchanged between the variable and check nodes during the integrity check process. A subset of these messages is selected and temporarily stored in the registers 232 as variable node data or check node data.

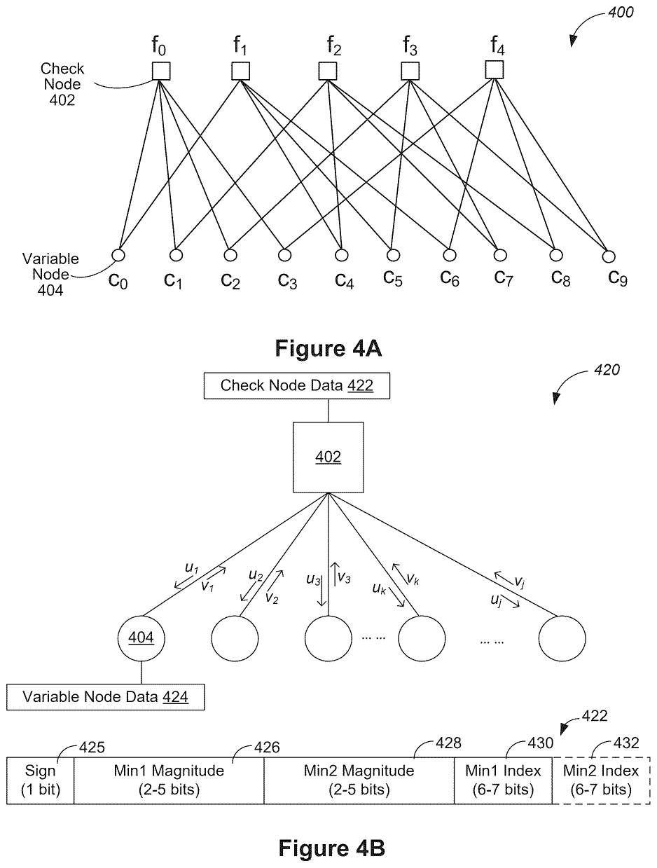

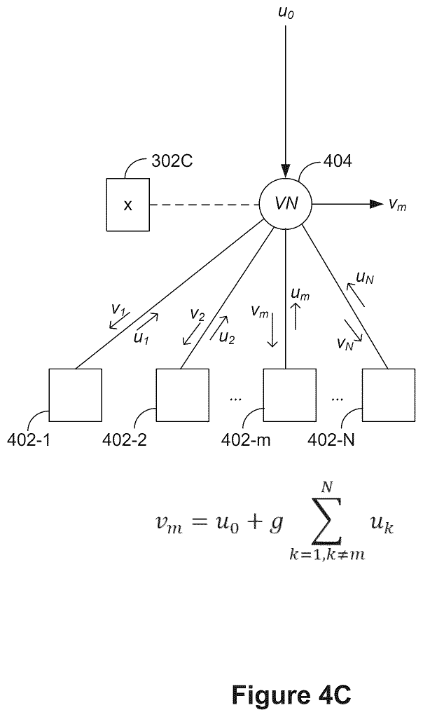

FIG. 3 is a block diagram of an example integrity check system 300 of a memory system 200 for processing a codeword 302, in accordance with some embodiments. The integrity check system 300 includes a plurality of memory channels 204, an integrity engine 230 (e.g., an LDPC engine), and a registers 232. Data stored in memory channels 204 of the memory system 200 (FIG. 2) is grouped into coding blocks, and each coding block is called a codeword 302. Each codeword 302 further includes n data bits among which k data bits are user data 302D and (n−k) data bits are integrity data 302I of the user data 302D, where k and n are positive integers. The integrity check system 300 is configured to verify data integrity for each codeword 302 of the memory channels 204 using variable nodes 404 and check nodes 402 (FIG. 4).

In some embodiments, the integrity engine 230 further includes one or more of: a compression module 304, an error correction code (ECC) encoder 306, a scrambler 308, a descrambler 310, an ECC decoder 312, and a decompression module 314. The compression module 304 obtains user data 302D and processes (e.g., compresses, encrypts) the user data 302D. The ECC encoder 306 obtains the user data 302D that is optionally processed by the compression module 304, and applies a parity data generation matrix G (316) on the user data 302D to encode the codeword 302. The matrix G (316) has k rows and n columns. A systematic form of the matrix G includes an identify matrix I configured to preserve the user data 302D within the codeword 302 and a parity matrix P configured to generate the integrity data 302I from the user data 302D. In some embodiments, the matrix G (316) is not unique and includes a set of basis vectors for a vector space of valid codewords 302. The scrambler 308 obtains the codeword 302 including n data bits and converts the n data bits to a scrambled codeword 318 having a seemingly random output string of n data bits. The scrambled codeword 318 is stored in the memory channels 204 of the memory system 200.

During decoding, the scrambled codeword 318 is extracted from the memory channel 204 of the memory system 200. The descrambler 310 recovers a codeword 302′ from the scrambled codeword 318, and the ECC decoder 312 verifies whether the recovered codeword 302′ is valid and corrects erroneous bits in the recovered codeword 302, thereby providing the valid codeword 302 including the valid user data 302D. In some embodiments, the decompression module 314 obtains the user data 302D and processes (e.g., decompresses, decrypts) the user data 302D. In some embodiments, for integrity check, the ECC decoder 312 applies a parity-check matrix H (320) on the recovered codeword 302′ to generate a syndrome vector S. The parity check matrix H (320) includes n−k rows corresponding to n−k parity check equations and n columns corresponding to n codeword bits. A relationship of the recovered codeword 302′ and the syndrome vector s is represented as follows:

$$S = y {H}^{T} \qquad ( 1 )$$

where y is the recovered codeword 302′. In some embodiments, in accordance with a determination that the syndrome s is equal to 0, the ECC decoder 312 determines that all parity-check equations associated with the parity-check matrix H are satisfied and that the recovered codeword 302′ is valid. Conversely, in accordance with a determination that the syndrome is not equal to 0, the ECC decoder 312 determines that at least a predefined number (e.g., one, two) parity check equation associated with the parity-check matrix H is not satisfied and that the recovered codeword 302′ is not valid. Alternatively, in some embodiments, the ECC decoder 312 operates to solve the following equation:

$$S = e {H}^{T} \qquad ( 2 )$$

where e is an error vector. The syndrome vector s is a combination of the error vector e and a valid codeword 302. Given that the syndrome vector s and the parity check matrix H are known, the ECC decoder 312 solves equation (2) to obtain the error vector e and identify the erroneous bits in the recovered codeword 302′.

FIG. 4A is a Tanner graph 400 applied to implement LDPC coding using check nodes 402 and variable nodes 404, in accordance with some embodiments. Data stored in a memory system 200 (FIG. 2) is verified on a codeword basis. Each codeword 302 includes n data bits among which k data bits are user data 302D and n−k data bits are integrity data 302I of the user data 302D, where k and n are positive integers. In some embodiments, the parity check matrix H (320) is applied without differentiating the user data 302D and the integrity data 302I during integrity check. The parity-check matrix H (320) includes n−k rows corresponding to n−k parity-check equations and n columns corresponding to n codeword bits, where k and n are positive integers. Each parity-check equation combines corresponding n codeword bits (also called codeword symbols), and therefore, corresponds to a check node 402 that is connected up to a subset or all of the n variable nodes 404. In some embodiments, only j codeword bits in the n codeword bits correspond to 1 in the parity check matrix H (320) for a row corresponding to check node 402, where j is an integer less than n, and the check node 402 is connected to the j variable nodes 404. In some embodiments, each and every check node 402 is connected to the same number of variable nodes 404 (e.g. j variable nodes 404). Alternatively, in some embodiments, each check node 402 is connected to a respective number of variable nodes 404, and at least two check nodes 402 are connected to different numbers of variable nodes 404.

Referring to FIG. 4A, in this example, the codeword 302 has 10 codeword symbols (also called codeword bits). Five parity check equations are applied to do integrity check on the codeword 302, and each parity check equation is applied on a set of four codeword symbols (j=4). As such, the Tanner graph 400 includes five check nodes 402 (f₀-f₄) and each check node 402 is connected to four respective variable nodes 404 each corresponding to a distinct set of four codeword symbols of the codeword 302.

In some embodiments, the ECC decoder 312 solves equation (2) to obtain the error vector e and identify one or more erroneous bits in the codeword 302 by an iterative integrity check process. Messages are exchanged between the variable nodes 404 and check nodes 402 on the Tanner graph 400 until the one or more erroneous bits are identified or corrected in the codeword 302. Each variable node 404 is assigned with initial variable node data 424. In some embodiments, the initial variable node data 424 includes a log-likelihood ratio (LLR) that is determined based on data measured when a read reference voltage is adjusted for the memory system 200. Each check node 402 is connected to a set of variable nodes 404, and receives messages including the initial variable node data 424 from the set of variable nodes 404. For each check node 402, the check node data is determined based on the initial variable node data 424 of the set of variable nodes 404, and indicates a likelihood of a set of codeword symbols corresponding to the set of variable nodes 404 being erroneous. Conversely, each variable node 404 is also connected to a set of check nodes 402 on the Tanner graph 400, and receives messages including the check node data from the set of check nodes 402. For each variable node 404, variable node data 424 is updated based on the check node data 422 of the set of variable nodes 404. By these means, the messages are exchanged between the check nodes 402 and variable nodes 404 until an integrity check requirement is satisfied, and the one or more erroneous bits are identified or corrected based on the variable node data 424 or the check node data. In some embodiments, the integrity check requirement is satisfied when sign 425 is 0 for all check nodes 402.

FIG. 4B is a simplified Tanner graph 420 having a single check node 402 coupled to a set of variable nodes 404, in accordance with some embodiments. Check node 402 receives variable-to-check node message data v₁, v₂, v₃, . . . vⱼ from j variable nodes 404, where j is also known as the degree of the check node, d_{c}. After a check node update is performed based on a min-sum algorithm, check node 402 sends check-to-variable node message data u₁, u₂, u₃, . . . uⱼ to de variable nodes 404. Details about the check node update calculation for k, where k is an integer in the range [1, d_{c}], are as follows:

$${u}_{k} = ( \text{?} sign ( {v}_{m} ) ) \times \text{?} \vert {v}_{m} \vert \qquad ( 3 )$$

$$sign ( {u}_{k} ) = ( \text{?} sign ( {v}_{m} ) ) \qquad ( 4 )$$

$$\vert {u}_{k} \vert = \text{?} \vert {v}_{m} \vert = \{ \begin{matrix}Min 2 Magnitude , k = Min 2 Index \\ Min 1 Magnitude , k = Min 1 Index\end{matrix} \qquad ( 5 )$$

$$\text{?} \text{indicates text missing or illegible when filed}$$

where Min1 and Min2 correspond to two variable nodes 404 having the most minimum variable-to-check node message magnitude and the second minimum variable-to-check node message magnitude, respectively. The check node data 422 includes a sign bit 425, a first likelihood data item 426 (Min1 Magnitude), a second likelihood data item 428 (Min2 Magnitude), and a first index data item 430 (Min1 Index). In accordance with equation (4), the sign bit 425 is generated based on signs of the variable-check node message data (v₁-vₘ) from the set of variable nodes 404. Stated another way, the sign bit 425 is a combination of signs of respective likelihood data items of a subset of codeword symbols corresponding to the set of variable nodes 404. The first likelihood data item 426 and the second likelihood data item 428 include magnitudes of the most minimum variable-to-check node message data (Min1) and the second minimum variable-to-check node message data (Min2) of the set of variable nodes 404, respectively. The first index data item 430 identifies one of the set of variable nodes 404 corresponding to the first likelihood data item 426. In some embodiments, the check node data 422 further includes a second index data item 432 identifying a second one of the set of variable nodes 404 corresponding to the second likelihood data item 428.

FIG. 4C is another simplified Tanner graph 420 having a single variable node 404 coupled to a set of check nodes 402, in accordance with some embodiments. Each single variable node 404 corresponds to a first data bit 302C (e.g., c₀, c₁, . . . , c₉ in FIG. 4A) of the codeword 302. Data bit is also called codeword symbol. The variable node 404 receives check-to-variable node message data u₁, u₂, u₃, . . . u_{N} (also called check node data) from N check nodes 402, where N is also known as a degree of the variable node 404. When a variable node update is performed based on a min-sum algorithm, each of the N check nodes 402 sends check-to-variable node message data u₁, u₂, u₃, . . . u_{N} to the same variable node 404. Variable-to-check node message data vₘ (also called variable node data 424) is further generated based on the check-to-variable node message data u₁-u_{N}, and sent from the variable node 404 to an m-th check node of the set of check nodes 402, where m is an integer in the range [1, N]. The variable-to-check node message data vₘ is represented as follows:

$${v}_{m} = {u}_{0} + {\sum }_{k = 1 , k \neq m}^{N} {u}_{k} \qquad ( 6 )$$

where u₀ is an intrinsic likelihood of the first data bit 302C in an example. In another example, u₀ is an intrinsic likelihood of the first data bit 302C being a logic bit 1. In yet another example, u₀ is an intrinsic likelihood of the first data bit 302C being erroneous. In some embodiments, a scaling factor g is used to multiply a sum of check-to-variable node message data, and the sum and an intrinsic likelihood u₀ (also called input LLR) in the variable node update are combined to generate the variable-to-check node message data vₘ as follows:

$${v}_{m} = {u}_{0} + g {\sum }_{k = 1 , k \neq m}^{N} {u}_{k} \qquad ( 7 )$$

where g is the scaling factor.

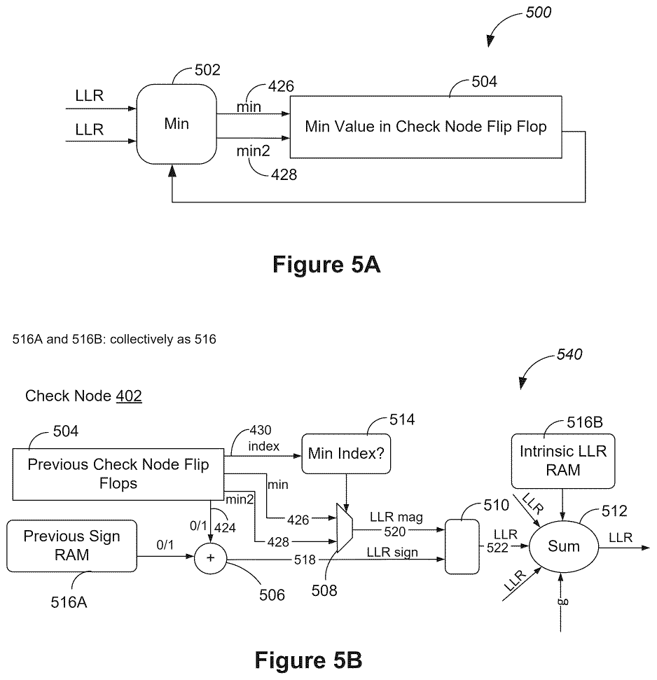

FIG. 5A is a schematic diagram of a sequence of check node operations 500 implemented to determine check node data of a check node 402 during LDPC decoding, in accordance with some embodiments. LDPC decoding is performed based on a min-sum method. An integrity engine 230 (FIG. 2) organizes a plurality of arithmetic units and a registers 232 to implement an instruction corresponding to the min-sum method without frequently interacting with a local memory processor 218. Specifically, each check node 402 corresponds to a parity-check equation that combines corresponding n codeword symbols (also called codeword bits), and is connected to a subset of the n variable nodes 404. In some embodiments, only j codeword symbols in the n codeword symbols are associated with non-zero coefficients in the parity-check equation, and the check node 402 is connected to the j variable nodes 404. For each check node 402, the plurality of arithmetic units includes a comparator operator 502 coupled to flip-flops 504 in a registers 232 (FIG. 2). The comparator operator 502 receives variable-to-check node message data from a subset of the j variable nodes 404 connected to the check node 402, and check node data 422, and determines the first likelihood data item 426 and the second likelihood data item 428, corresponding to the most minimum variable-to-check node message data (Min1) and the second minimum variable-to-check node message data (Min2) of the set of j variable nodes 404, respectively. The first likelihood data item 426 and the second likelihood data item 428 are stored into the flip flops 504 of the registers 232. In some embodiments, the variable-to-check node message data from each of the set of j variable nodes 404 includes an LLR that is determined based on data measured when a read reference voltage is adjusted for the memory system 200.

FIG. 5B is a schematic diagram of a sequence of check node and variable node operations 540 implemented to determine variable-to-check node message data vₘ from a variable node 404 during LDPC decoding, in accordance with some embodiments. For each variable node 404, the plurality of arithmetic units organized by the integrity engine 230 includes a sign operator 506, a multiplexer 508, a combiner 510, a sum operator 512, an index identifier 514, and one or more random access memory (RAM) 516. The RAM 516 stores data involved in the check node and variable node operations 540 temporarily. In some embodiments, the registers 232 further includes the RAM 516 associated with these check node and variable node operations 540. Each variable node 404 is connected to a set of check nodes 402, and applied in a set of parity-check equations corresponding to the set of check nodes 402. One of the set of check nodes 402 corresponds to check node data stored in the flip-flops 504 and including a sign bit 425, a first likelihood data item 426, a second likelihood data item 428, and a first index data item 430. A previous variable-to-check node message data sign stored in a RAM 516A is combined with the sign bit 425 by the sign operator 506 to form an LLR sign 518. The index identifier 514 compares an index k of the variable node 404, which uniquely identifies one variable node 404 among the j variable nodes connected to one check node 402, with the first index data item 430. In accordance with a comparison result, the multiplexer 508 selects one of the likelihood data items 426 and 428 as a likelihood data item 520, and the combiner 510 generates a signed LLR data item 522 that is sent from check node 402 to variable node 404 based on the LLR sign 518 and likelihood data item 520 (e.g., a value of uₖ in equations (6) and (7)). Specifically, in some embodiments, in accordance with a determination that the index k of the variable node 404 is equal to the first index data item 430, the multiplexer 508 selects the second likelihood data item 428 as the likelihood data item 520 (e.g., a value of uₖ in equations (6) and (7)). Conversely, in some embodiments, in accordance with a determination that the index k of the variable node 404 is not equal to the first index data item 430, the multiplexer 508 selects the first likelihood data item 426 as the likelihood data item 520.

In some embodiments, intrinsic LLR data (e.g., intrinsic likelihood u₀) corresponds to initial variable node data of each variable node 404 associated with a respective codeword symbol of a codeword 302. The intrinsic LLR data is determined based on a log-likelihood ratio (LLR) that is approximated as follows:

$$L L R ( y ) = ln \frac{p ( x = 0 \vert y )}{p ( x = 1 \vert y )} = ln \frac{p ( y \vert x = 0 )}{p ( y \vert x = 1 )} \qquad ( 8 )$$

where p(|) is a probability of a combination of data values, x is a value stored for the respective codeword symbol, and y is a correct value of the respective codeword symbol. The intrinsic LLR data is determined based on data measured when a read reference voltage is adjusted for the memory system 200.

The sum operator 512 combines intrinsic LLR data stored in the RAM 516B, LLR data items 522 (e.g., uₖ in equations (6) and (7)), and scaling factor g for the set of check nodes 402 to update the variable node data 424 (e.g., variable-to-check node message data vₘ) associated with the variable node 404.

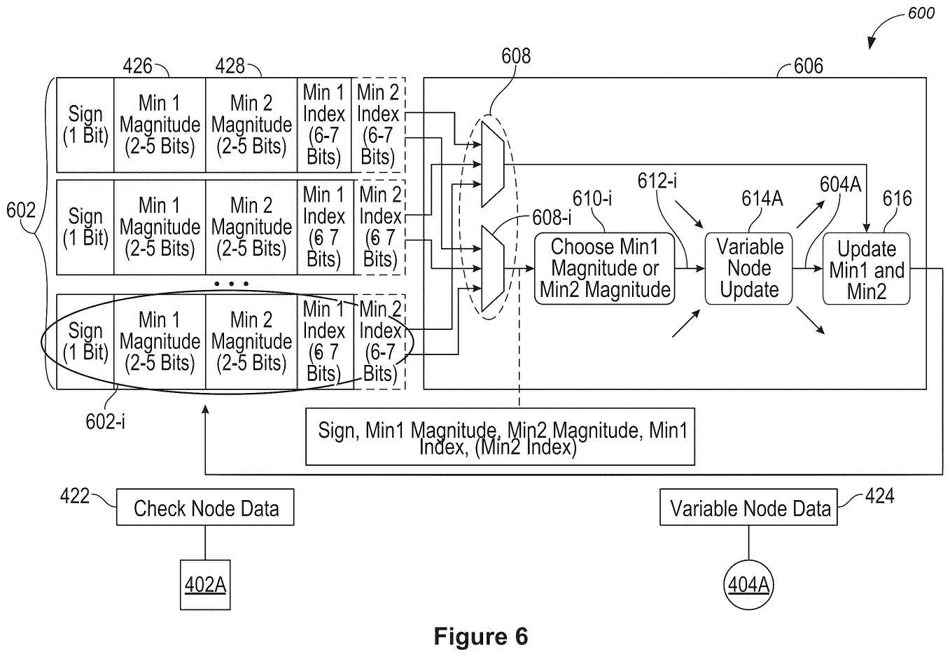

FIG. 6 is a schematic diagram of an example circuit 600 for updating variable node data 424 based on check node data 422, in accordance with some embodiments. The check node data 422 include a plurality of check node data items 602 each of which includes a plurality of data bits and corresponds to a respective check node 402. More details on each check node data item 602 are explained above with reference to FIGS. 4A-4C. The plurality of check node data items 602 are provided to a logic 606 and processed by the logic 606 to generate a variable node data item 604A of a first variable node 404A. The first variable node 404A has a variable node degree K indicating that the first variable node 404A is connected to a first set of check node 402A including K check nodes. Each check node 402 further has a respective node degree L indicating that the respective check node 402 is connected to a respective set of variable nodes 404 including L variable nodes.

In some embodiments, the logic 606 includes a plurality of multiplexers 608 (e.g., including K multiplexers), and a multiplexer 608-i is configured to receive a subset of respective check node data items 602 and select a respective check node data item 602-i. The logic 606 further includes a magnitude selector 610-i coupled to the multiplexer 608-i to further select one of a first likelihood data item 426 (Min1 Magnitude) and a second likelihood data item 428 (Min2 Magnitude) of the respective check node data item 602-i. A selected data item 612-i is provided to a variable node updater 614A, and the variable node updater 614A consolidates the selected data items associated with each of the first set of check nodes 402A to update the variable node data item 604A of the first variable node 404A, e.g., based on equation (6) or (7). Further, in some embodiments, the logic 606 further includes a check node updater 616, and the check node updater 616 receives a set of variable nodes 404 coupled to a corresponding check node 402 to update the first likelihood data item 426 (Min1 Magnitude) and the second likelihood data item 428 (Min2 Magnitude) of the respective check node data item 602-i.

In some embodiments, LDPC codes (e.g., data items 602 and 604A) are decoded to correct bit errors using an iterative message passing method (e.g., a bit flipping algorithm (BFA), a min-sum algorithm (MSA), or a sum-of-product algorithm (SPA)), which may be visualized on a Tanner graph 400. Messages carrying check node data 422 (FIG. 4B) and variable node data 424 are exchanged between check nodes 402 and variable nodes 404. In some embodiments (e.g., associated with the BFA or MSA), a set of check node data 422 is temporarily stored in flip-flops, multiplexed, and selected for further processing during each clock cycle. For example, a min-sum decoder operates on variable nodes 404 that represent codeword bits and check nodes 402 that represent parity-check equations. During a decoding iteration, variable node data 424 of a variable node is selectively set to 0 to adjust variable node data 424 (e.g., in a variable-to-check node message) sent by a variable node to a connected check node. This operation controls an iteration rate of error correction, and is adaptively applied based on one or more conditions of: (1) whether the variable node data 424 have been updated with an opposite sign, (2) whether the variable node has provided the lowest variable node data 424 in too many associated check nodes 402, and/or (3) whether a syndrome weight of a block of data corresponding to the variable node is too large. By these means, some implementations of this application provide an accurate and efficient error correction solution to manage variable node data 424 of variable nodes 404 of user data and enhance error correction strength and rate of a corresponding memory system 200 (e.g., a QLC NAND memory flash).

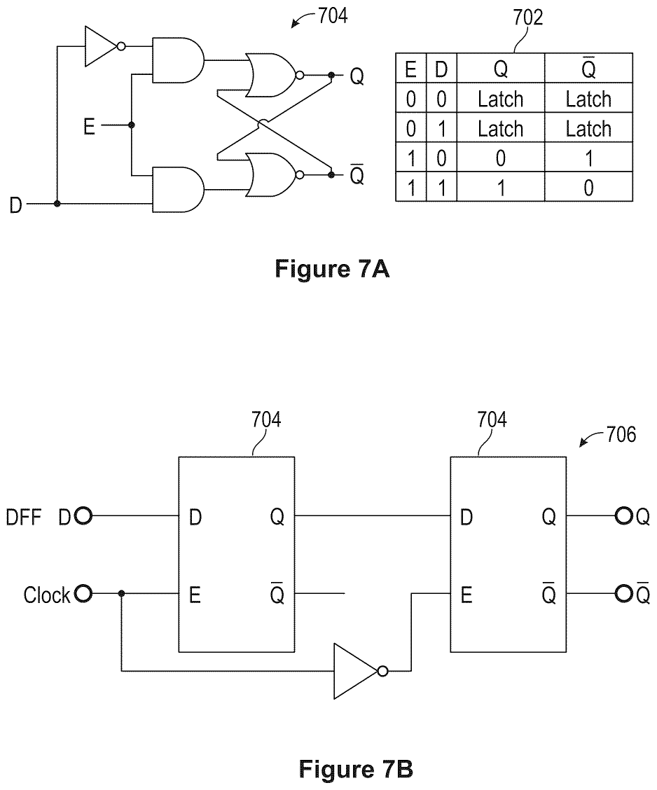

FIG. 7A illustrates a schematic diagram and an associated truth table 702 of an example latch circuit 704 (e.g., a gated D latch), in accordance with some embodiments. FIG. 7B is a schematic diagram of an example flip-flop circuit 706 (e.g., a D flip-flop (DFF)), in accordance with some embodiments. Gated D latches are smaller than D flip-flops. For example, a D latch corresponds to approximately 3.3 gates, and a D flip-flop corresponds to 6.8 gates. An edge-triggered D flip-flops can hold a value for a full clock cycle. A data input at D will be held at the output at Q until the clock input transitions from “0” to “1.” Conversely, a gated D latch is level-sensitive, and is configured to hold a digital value (e.g., “0,” “1”) for a half of a clock cycle. When an input control signal E is enabled, the latch generates an output Q that tracks the input data D. When the input control signal E is disabled, the output Q holds its signal value generated while the input control signal E is enabled. A set of two D latches form a master-slave D flip-flop, which is configured to hold the digital value for a full clock cycle.

Referring to FIG. 7B, in some implementations, the DFF includes two D latches 704 arranged in series and an inverter, and a number of transistor included in the DFF is at least twice of that of the D latch 704. Since two latches in series can act like a flip-flop, use a larger number of latches to store the check node data items 602 and hold them stable for the first half of a clock period, which feed the multiplexers 608. The multiplexers 608 pass a smaller number of bits to a smaller number of latches to store selected check node data items or bits to be held stable for the second half of the clock period.

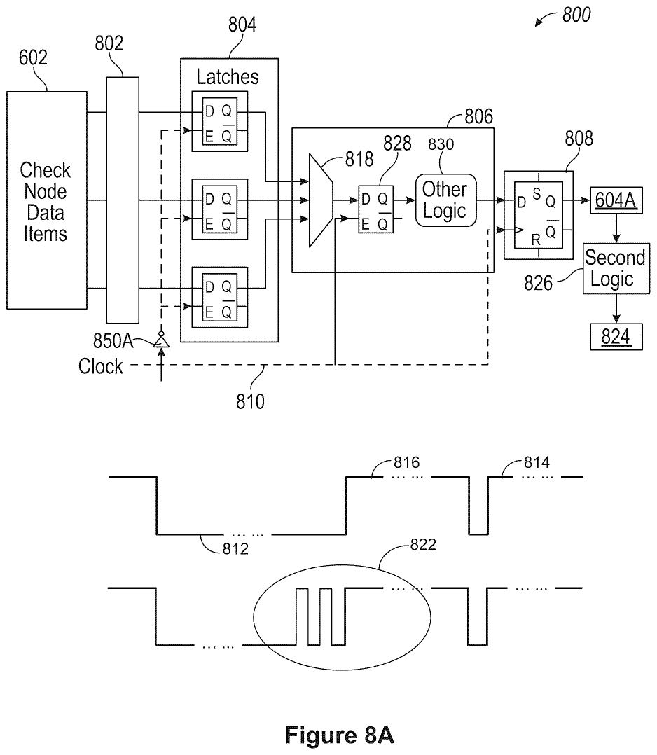

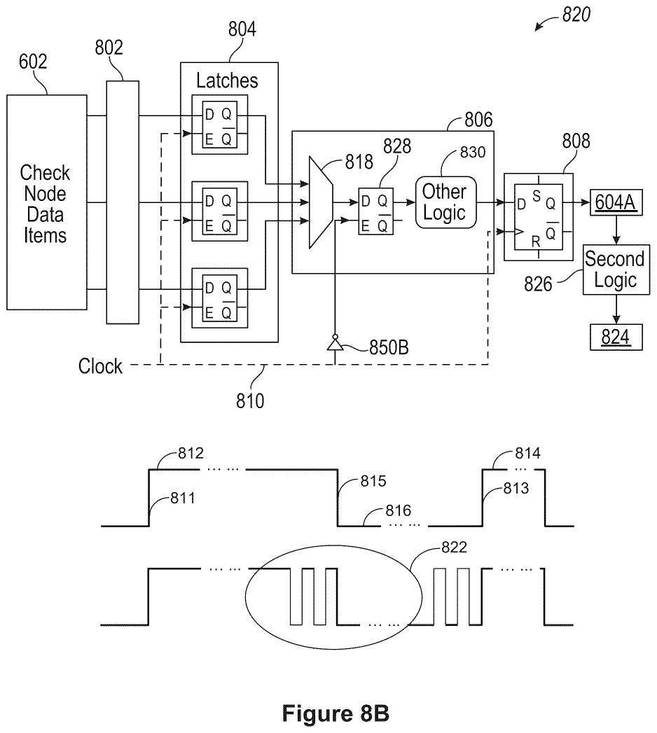

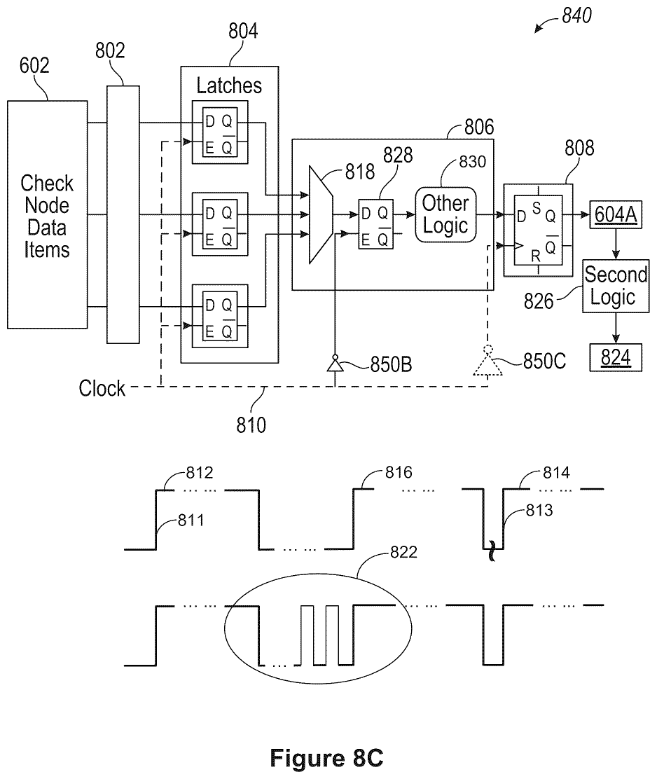

FIGS. 8A, 8B, and 8C are schematic diagrams of three example latch-based circuits 800, 820, and 840 for processing check node data 422 (e.g., check node data items 602) of a plurality of check nodes 402, in accordance with some embodiments, respectively. Each latch-based circuit 800, 820, or 840 includes an input data interface 802, a plurality of input latch units 804, a logic 806, and an output unit 808. The input data interface 802 receives a plurality of check node data items 602, and each check node data item 602 includes a plurality of parallel input bits. For example, the plurality of parallel input bits of a check node data item 602 includes a sign bit 425, a first likelihood data item 426 (Min1 Magnitude), a second likelihood data item 428 (Min2 Magnitude), and a first index data item 430 (Min1 Index), and have 17 bits in total. The plurality of input latch units 804 are coupled to the input data interface 802. Each input latch unit 804 corresponds to a respective check node data item 602 (e.g., data item 602-i having 17 bits) and includes a plurality of parallel input latches (e.g., 17 D latches 704) configured to be controlled by a control signal 810 to hold the plurality of parallel input bits of the respective check node data item 602. In an example, the control signal 810 includes a clock signal having a feature frequency. The logic 806 is coupled to the plurality of input latch units 804, and configured to process the plurality of check node data items 602 and generate a variable node data item 604A including a plurality of parallel output bits. The output unit 808 is coupled to the logic 806 and includes a plurality of parallel output latches (e.g., 17 D latches 704) configured to be controlled by the control signal 810 to hold the plurality of parallel output bits of the variable node data item 604A.

In some embodiments, the control signal 810 includes a periodic signal. The plurality of input latch units 804 are configured to refresh the parallel input bits of the plurality of check node data items 602 during each periodic cycle of the periodic signal and hold the parallel input bits of the plurality of check node data items for a first high or low duty cycle of each periodic signal. The output unit 808 includes a latch. For example, referring to FIG. 8A, each input latch unit 804 refreshes reading of the input bits of the check node data items 602 during each low duty cycle of the periodic signal, and the output latch unit refreshes reading of the output bits of the variable node data item 604A during each high duty cycle of the periodic signal. Referring to FIGS. 8B and 8C, in some situations, each input latch unit 804 and the output unit 808 refreshes reading of the input bits of the check node data items 602 and the output bits of the variable node data item 604A during each high duty cycle of the periodic signal, respectively.

In some embodiments, the control signal 810 includes a periodic signal configured to synchronize operation of the plurality of input latch units 804 and the output unit 808 according to a feature frequency. Further, in some embodiments, the plurality of input latch units 804 are configured to hold bit values of the parallel input bits of the plurality of check node data items 602 for a first half 812 of a first periodic cycle, and the output unit 808 is configured to hold the plurality of parallel output bits, which are generated based on the bit values held by the input latch units for the first half 812 of the first periodic cycle, at a second half 814 of a second periodic cycle subsequent to the first half 812 of the first periodic cycle.

In some embodiments, the second half 814 of the second periodic cycle is temporally separated from the first half 812 of the first periodic cycle by at least one half 816 of a feature periodic cycle corresponding to the feature frequency of the periodic signal. Further, in some embodiments, the second half 814 of the second periodic cycle is temporally separated from the first half 812 of the first periodic cycle by multiple clock cycles 822. The logic 806 includes a synchronous sequential circuit configured to be controlled by the control signal 810 to generate the variable node data item based on the plurality of check node data items 602 within the at least one half 816 of the feature periodic cycle. The synchronous sequential circuit may include at least one select latch unit 828.

Additionally, referring to FIG. 8B, in some embodiments, the first half 812 of the first periodic cycle immediately follows a first rising edge 811 of the periodic signal, and the second half 814 of the second periodic cycle immediately follows a second rising edge 813 of the control signal that follows the first rising edge and is separated from the first rising edge 811 by a first falling edge 815, and the logic is configured to operate after the first falling edge 815 of the periodic signal.

In some embodiments not shown, the logic 806 includes an asynchronous combinational logic circuit configured to generate the variable node data item 604A based on the plurality of check node data items 602 within a half (e.g., the at least one half 816 in FIGS. 8A-8C) of a feature periodic cycle of the periodic signal. The logic 806 does not include any latch or flip-flop that is controlled by the periodic signal. Further, in some embodiments, the first half 812 of the first periodic cycle corresponds to a rising edge of the periodic signal, and the second half 814 of the second periodic cycle corresponds to a rise or falling edge of the control signal 810 that immediately follows the rising edge of the periodic signal. Conversely, in some embodiments, the first half 812 of the first periodic cycle corresponds to a falling edge of the periodic signal, and the second half 814 of the second periodic cycle corresponds to a rising edge of the control signal that immediately follows the falling edge of the periodic signal.

In some embodiments, each of the plurality of input latch units 804 and the output unit 808 includes a respective D latch 704.

In some embodiments, the variable node data item 604A corresponds to a variable node 404A representing one of a plurality of user data symbols (e.g., a data bit in a codeword 302), and a subset of the plurality of check node data items 602 corresponds to a plurality of check nodes 402 coupled to the variable node 404A in an LDPC process.

In some embodiments, the logic 606 further includes a multiplexer 818 (e.g., multiplexer 608-i) configured to select a subset of the plurality of check node data items 602 (e.g., corresponding to a first set of check nodes 402A in FIG. 6) for generating the variable node data item 604A. In some embodiments, the logic 606 further includes a select latch unit 828 coupled to the multiplexer 818, and configured to hold the subset of selected check node data items 602 for further process during a respective clock cycle. Alternatively, in some embodiments, the logic 606 further includes a DFF in place of the select latch unit 828. In some embodiments, the logic 606 further includes other logic 830 coupled to the select latch unit 828, and the other logic 830 may include a magnitude selector 610-i and a variable node updater 614A.

Further, in some embodiments, each of the plurality of check node data items 602 includes a set of likelihood data items (e.g., a first likelihood data item 426 (Min1 Magnitude), a second likelihood data item 428 (Min2 Magnitude)). The logic 806 is configured to process the subset of the plurality to check node data items 602 based on equation (6), e.g., by selecting a respective likelihood data item of each check node data item, generating a sum of respective likelihood data items of the subset of the plurality of check node data items 602, and combining the sum and an intrinsic log-likelihood ratio (LLR) corresponding to the variable node data item 604A. Additionally, in some embodiments, the logic 806 is configured to process the plurality of check node data items based on equation (7), e.g., by scaling the sum of respective likelihood data items of the subset of the plurality of check node data items by a scaling factor g to generate a scaled sum, and the scaled sum is combined with the intrinsic LLR to generate the variable node data item 604A.

In some embodiments, the logic 806 includes a first logic. A second logic 826 is coupled to the output unit 808, and configured to process the variable node data item 604A to generate an output data item 824 while the variable node data item 604A is held by the output unit 808.

In some embodiments, the output unit 808 further includes a D latch 704 configured to be controlled by the control signal 810 to refresh the variable node data item 604A during each periodic cycle of the periodic signal and hold the parallel output bits of the variable node data item 604A for a high or low duty cycle of each periodic cycle. Alternatively, in some embodiments, the output unit 808 further includes an edge-triggered flip-flop 706 including two D latches 704 coupled to each other and configured to be controlled by the control signal 810 to hold the output data item 604A during each periodic cycle.

In some embodiments, each of the input latch units 804, the select latch unit 828, and the latch or DFF of the output unit 808 is controlled by a respective one of a clock signal or an inverted clock signal. For example, if the input latch units 804 are controlled by the inverted clock signal, an inverter 850A (FIG. 8A) is applied to invert the clock signal before the clock signal is fed to control the input latch units 804. Similarly, if the select latch unit 828 and the latch or DFF of the output unit 808 is controlled by the inverter signal, inverters 850B and 850C (FIG. 8C) are applied to invert the clock signal.

Logic design is much easier with D flip-flops when check node data bits are stored and multiplexed. The check node data bits are provided from different check nodes, and selected for processing using a multiplexer. Input latches are applied during first halves of clock cycles, and output latches are applied during second halves of the clock cycles. In an example, a decoder includes four min-sum check nodes 402 each having 17-bit check node data 422, two 4:1 multiplexers per check node, and interface flip-flops (which is not considered in the gate count). The two multiplexers are controlled by a clock signal having 1 ns clock periods. If implemented with flip-flops, the decoder includes 737 gates; conversely, if implemented with latches, the decoder includes 635 gates, which corresponds to 102 gates saved for every 68 bits of check node data 422 (i.e., 1.5 gates saved for each bit of check node data 522). For a data block having 5120 check nodes, 130 K gates may be saved for the decoder applied to implement LDPC.

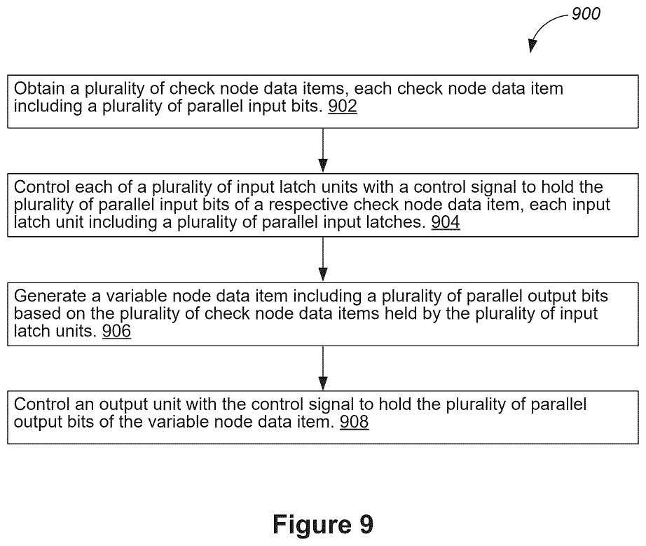

FIG. 9 is a flow diagram of an example process 900 for processing check node data, in accordance with some embodiments. An electronic device includes an input data interface, a plurality of input latch units coupled to the input data interface, a logic coupled to the plurality of input latch units, and an output unit coupled to the logic. The input data interface obtains (operation 902) a plurality of check node data items, and each check node data item includes a plurality of parallel input bits. Each input latch unit corresponds to a respective check node data item and includes a plurality of parallel input latches. The plurality of input data units are controlled (operation 904) by a control signal to hold the plurality of parallel input bits of the respective check node data item. The logic processes the plurality of check node data items and generate (operation 906) a variable node data item including a plurality of parallel output bits. The output unit is controlled (operation 908) by the control signal to hold the plurality of parallel output bits of the variable node data item.

In some embodiments, the control signal includes a periodic signal. The plurality of input latch units refresh the parallel input bits of the plurality of check node data items during each periodic cycle of the periodic signal and hold the parallel input bits of the plurality of check node data items for a first high or low duty cycle of each periodic cycle.

In some embodiments, the control signal includes a periodic signal configured to synchronize operation of the plurality of input latch units and the output unit according to a feature frequency. Further, in some embodiments, the plurality of input latch units hold bit values of the parallel input bits of the plurality of check node data items for a first half of a first periodic cycle, and the output unit holds the plurality of parallel output bits, which are generated based on the bit values held by the input latch units for the first half of the first periodic cycle, at a second half of a second periodic cycle subsequent to the first half of the first periodic cycle. Additionally, in some embodiments, the second half of the second periodic cycle is temporally separated from the first half of the first periodic cycle by at least one half of a feature periodic cycle. The logic includes a synchronous sequential circuit controlled by the control signal to generate the variable node data item based on the plurality of check node data items within the at least one half of the feature periodic cycle.

In some embodiments, the first half of the first periodic cycle immediately follows a first rising edge of the periodic signal, and the second half of the second periodic cycle immediately follows a second rising edge of the control signal that follows the first rising edge and is separated from the first rising edge by a first falling edge. The logic operates after the first falling edge of the periodic signal.

In some embodiments, the logic includes an asynchronous combinational logic circuit that generates the variable node data item based on the plurality of check node data items within a half of a feature periodic cycle of the periodic signal. Additionally, in some embodiments, the first half of the first periodic cycle corresponds to a rising edge of the periodic signal, and the second half of the second periodic cycle corresponds to a falling edge of the control signal that immediately follows the rising edge of the periodic signal. In some embodiments, the first half of the first periodic cycle corresponds to a falling edge of the periodic signal, and the second half of the second periodic cycle corresponds to a rising edge of the control signal that immediately follows the falling edge of the periodic signal.

In some embodiments, each of the plurality of input latch units and the output unit includes a respective D latch.

In some embodiments, the variable node data item corresponds to a variable node representing one of a plurality of user data symbols, and a subset of the plurality of check node data items corresponds to a plurality of check nodes coupled to the variable node in a low density parity check process.

In some embodiments, the logic further includes a multiplexer, and the multiplexer selects a subset of the plurality of check node data items for generating the variable node data item. Further, in some embodiments, each of the plurality of check node data items includes a set of likelihood data items, and the logic processes the subset of the plurality to check node data items by selecting a respective likelihood data item of each check node data item, generating a sum of respective likelihood data items of the subset of the plurality of check node data items, and combining the sum and an intrinsic log-likelihood ratio (LLR) corresponding to the variable node data item. Further, in some embodiments, the logic processes the plurality of check node data items by scaling the sum of respective likelihood data items of the subset of the plurality of check node data items by a scaling factor to generate a scaled sum, and the scaled sum is combined with the intrinsic LLR to generate the variable node data item.

In some embodiments, the logic includes a first logic, and the electronic device further includes a second logic coupled to the output unit, the second logic processes the variable node data item to generate an output data item while the variable node data item is held by the output unit.

In some embodiments, the output unit further includes a D latch having a plurality of parallel output latches. The plurality of parallel output latches are controlled by the control signal to refresh the variable node data item during each periodic cycle of a periodic signal and hold the parallel output bits of the variable node data item for a high or low duty cycle of each periodic cycle.

In some embodiments, the output unit further includes an edge-triggered flip-flop including two D latches coupled to each other, and is controlled by the control signal to hold the variable node data item during each periodic cycle.

Memory is also used to store instructions and data associated with the method 900, and includes high-speed random-access memory, such as SRAM, DDR DRAM, or other random access solid state memory devices; and, optionally, includes non-volatile memory, such as one or more magnetic disk storage devices, one or more optical disk storage devices, one or more flash memory devices, or one or more other non-volatile solid state storage devices. The memory, optionally, includes one or more storage devices remotely located from one or more processing units. Memory, or alternatively the non-volatile memory within memory, includes a non-transitory computer readable storage medium. In some embodiments, memory, or the non-transitory computer readable storage medium of memory, stores the programs, modules, and data structures, or a subset or superset for implementing method 900. Alternatively, in some embodiments, the electronic device implements the method 900 at least partially based on an ASIC. The memory system 200 of the electronic device includes an SSD in a data center or a client device.

Each of the above identified elements may be stored in one or more of the previously mentioned memory devices, and corresponds to a set of instructions for performing a function described above. The above identified modules or programs (i.e., sets of instructions) need not be implemented as separate software programs, procedures, modules or data structures, and thus various subsets of these modules may be combined or otherwise re-arranged in various embodiments. In some embodiments, the memory, optionally, stores a subset of the modules and data structures identified above. Furthermore, the memory, optionally, stores additional modules and data structures not described above.

The terminology used in the description of the various described implementations herein is for the purpose of describing particular implementations only and is not intended to be limiting. As used in the description of the various described implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. Additionally, it will be understood that, although the terms “first,” “second,” etc. may be used herein to describe various elements, these elements should not be limited by these terms. These terms are only used to distinguish one element from another.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software or any combination thereof.

What is claimed is:

1. An electronic device, comprising:
an input data interface configured to receive a plurality of check node data items, each check node data item including a plurality of parallel input bits;
a plurality of input latch units coupled to the input data interface, wherein each input latch unit corresponds to a respective check node data item and includes a plurality of parallel input latches configured to be controlled by a control signal to hold the plurality of parallel input bits of the respective check node data item;
a logic coupled to the plurality of input latch units, the logic configured to process the plurality of check node data items and generate a variable node data item including a plurality of parallel output bits; and
an output unit coupled to the logic, wherein the output unit is configured to be controlled by the control signal to hold the plurality of parallel output bits of the variable node data item.

2. The electronic device of claim 1, wherein:
the control signal includes a periodic signal; and
the plurality of input latch units are configured to refresh the parallel input bits of the plurality of check node data items during each periodic cycle of the periodic signal and hold the parallel input bits of the plurality of check node data items for a first high or low duty cycle of each periodic cycle.

3. The electronic device of claim 1, wherein the control signal includes a periodic signal configured to synchronize operation of the plurality of input latch units and the output unit according to a feature frequency.

4. The electronic device of claim 3, wherein the plurality of input latch units are configured to hold bit values of the parallel input bits of the plurality of check node data items for a first half of a first periodic cycle, and the output unit is configured to hold the plurality of parallel output bits, which are generated based on the bit values held by the input latch units for the first half of the first periodic cycle, at a second half of a second periodic cycle subsequent to the first half of the first periodic cycle.

5. The electronic device of claim 4, wherein:
the second half of the second periodic cycle is temporally separated from the first half of the first periodic cycle by at least one half of a feature periodic cycle; and
the logic includes a synchronous sequential circuit configured to be controlled by the control signal to generate the variable node data item based on the plurality of check node data items within the at least one half of the feature periodic cycle.

6. The electronic device of claim 4, wherein the first half of the first periodic cycle immediately follows a first rising edge of the periodic signal, and the second half of the second periodic cycle immediately follows a second rising edge of the control signal that follows the first rising edge and is separated from the first rising edge by a first falling edge, and the logic is configured to operate after the first falling edge of the periodic signal.

7. The electronic device of claim 4, wherein the logic includes an asynchronous combinational logic circuit configured to generate the variable node data item based on the plurality of check node data items within a half of a feature periodic cycle of the periodic signal.

8. The electronic device of claim 7, wherein the first half of the first periodic cycle corresponds to a rising edge of the periodic signal, and the second half of the second periodic cycle corresponds to a falling edge of the control signal that immediately follows the rising edge of the periodic signal.

9. The electronic device of claim 7, wherein the first half of the first periodic cycle corresponds to a falling edge of the periodic signal, and the second half of the second periodic cycle corresponds to a rising edge of the control signal that immediately follows the falling edge of the periodic signal.

10. The electronic device of claim 1, wherein each of the plurality of input latch units and the output unit includes a respective D latch.

11. The electronic device of claim 1, wherein the variable node data item corresponds to a variable node representing one of a plurality of user data symbols, and a subset of the plurality of check node data items corresponds to a plurality of check nodes coupled to the variable node in a low density parity check process.

12. The electronic device of claim 1, wherein the logic further comprises:
a multiplexer, which is configured to select a subset of the plurality of check node data items for generating the variable node data item; and
a select latch unit coupled to the multiplexer 818, wherein the select latch unit is configured to hold the subset of selected check node data items 602.

13. The electronic device of claim 12, wherein each of the plurality of check node data items includes a set of likelihood data items, and the logic is configured to process the subset of the plurality to check node data items by:
selecting a respective likelihood data item of each check node data item;
generating a sum of respective likelihood data items of the subset of the plurality of check node data items; and
combining the sum and an intrinsic log-likelihood ratio (LLR) corresponding to the variable node data item.

14. The electronic device of claim 13, wherein the logic is configured to process the plurality of check node data items by:
scaling the sum of respective likelihood data items of the subset of the plurality of check node data items by a scaling factor to generate a scaled sum, and the scaled sum is combined with the intrinsic LLR to generate the variable node data item.

15. The electronic device of claim 1, wherein the logic includes a first logic, and the electronic device further comprising:
a second logic coupled to the output unit, the second logic configured to process the variable node data item to generate an output data item while the variable node data item is held by the output unit.

16. The electronic device of claim 1, wherein the output unit further includes a D latch having a plurality of parallel output latches configured to be controlled by the control signal to refresh the variable node data item during each periodic cycle of a periodic signal and hold the parallel output bits of the variable node data item for a high or low duty cycle of each periodic cycle.

17. The electronic device of claim 1, wherein the output unit further includes an edge-triggered flip-flop including two D latches coupled to each other and configured to be controlled by the control signal to hold the variable node data item during each periodic cycle.

18. A non-transitory computer-readable medium storing one or more programs configured for execution by one or more processors of a memory device, the one or more programs comprising instructions for:
obtaining a plurality of check node data items, each check node data item including a plurality of parallel input bits;
controlling each of a plurality of input latch units with a control signal to hold the plurality of parallel input bits of a respective check node data item, each input latch unit including a plurality of parallel input latches;
generate a variable node data item including a plurality of parallel output bits based on the plurality of check node data items held by the plurality of input latch units; and
controlling an output unit with the control signal to hold the plurality of parallel output bits of the variable node data item.

19. A method, comprising:
obtaining a plurality of check node data items, each check node data item including a plurality of parallel input bits;
controlling each of a plurality of input latch units with a control signal to hold the plurality of parallel input bits of a respective check node data item, each input latch unit including a plurality of parallel input latches;
generating a variable node data item including a plurality of parallel output bits based on the plurality of check node data items held by the plurality of input latch units; and
controlling an output unit with the control signal to hold the plurality of parallel output bits of the variable node data item.

20. The method of claim 19, wherein:
the control signal includes a periodic signal; and
the plurality of input latch units are configured to refresh the parallel input bits of the plurality of check node data items during each periodic cycle of the periodic signal and hold the parallel input bits of the plurality of check node data items for a first high or low duty cycle of each periodic cycle.
